(19) United States
(12) Patent Application Publication
(10) Pub. No.: US 2026/0182382 A1
(43) Pub. Date: Jun. 25, 2026

(54) PANEL COMPRISING PACKAGING SUBSTRATE

(71) Applicant: Absolics Inc., Covington, GA (US)

(72) Inventors: Jincheol KIM, Hwaseong-si (KR); SeHan YUN, Covington, GA (US)

(73) Assignee: Absolics Inc., Covington, GA (US)

(21) Appl. No.: 19/369,344

(22) Filed: Oct. 27, 2025

Related U.S. Application Data
(60) Provisional application No. 63/736,579, filed on Dec. 19, 2024.

(51) Int. Cl. H01L 23/00; H01L 23/15

(52) U.S. Cl. CPC H10W 42/121; H10W 70/692

(57) ABSTRACT

According to the embodiment, a panel comprises a glass core having a width or length of 10 cm or more, and an upper layer disposed on the glass core and having redistribution lines therein. A unit refers to a portion in which a semiconductor element is disposed within a die layout and is separated into an individual packaging substrate. A plurality of the units are disposed on the panel. A reinforcement structure is disposed on the upper layer, configured to surround at least a portion of the die layout. A first unit comprises a first die layout and a first reinforcement structure disposed on the first die layout. A second unit comprises a second die layout and a second reinforcement structure disposed on the second die layout. The second unit is disposed adjacent to one side of the first unit, and the first reinforcement structure and the second reinforcement structure are disposed separately from each other.

### CROSS-REFERENCE TO RELATED APPLICATION

This application claims the priority of U.S. Provisional Patent Application No. 63/736,579, filed Dec. 19, 2024, the entire disclosures of which are incorporated herein by reference for all purposes.

### BACKGROUND

### Technical Field

The embodiment relates to a panel comprising individual packaging substrates, in which a reinforcement structure advantageous for processing a large-area substrate is disposed.

### Description of Related Art

In the manufacture of electronic components, implementing circuits on a semiconductor wafer is referred to as the front-end process (FE), and assembling the wafer into a state usable in actual products is referred to as the back-end process (BE), wherein the packaging process is included in the back-end process.

Recently, the four core technologies of the semiconductor industry that have enabled the rapid advancement of electronic devices are semiconductor technology, semiconductor packaging technology, manufacturing process technology, and software technology. Semiconductor technology has evolved in various forms, including sub-micron or nanometer-scale line widths, over tens of millions of cells, high-speed operation, and high heat generation. However, the technology for perfectly packaging such semiconductors has not kept pace. Accordingly, the electrical performance of a semiconductor may be determined not only by the semiconductor technology itself but also by the packaging technology and the associated electrical connections.

Ceramic or resin materials are typically used for packaging substrates. However, in recent years, research has been conducted on applying silicon or glass as high-end packaging substrates, and in particular, a packaging substrate having a cavity structure formed using a glass substrate has been developed.

Glass may be implemented in a large area and has a brittle nature. A glass panel is likely to warp during processing, and thus, a method for suppressing warpage and preventing glass breakage is required.

The foregoing background technologies are technical information possessed by the inventors for deriving the embodiment, or acquired in the course of derivation, and cannot necessarily be regarded as related art disclosed to the general public before the filing of the present disclosure.

Related arts include Korean Patent Publication No. 10-2022-0166644, Korean Patent Publication No. 10-2023-0067496, and U.S. Patent Application Publication No. US20240014147.

### SUMMARY

In some embodiments, a panel comprising individual packaging substrates, in which a reinforcement structure advantageous for large-area substrate processing is disposed.

In some embodiments, a panel having a reinforcement structure that may suppress glass breakage and reduce warpage during large-area substrate processing.

According to an embodiment, a panel according to an embodiment comprises: a glass core having a width or length of 10 cm or more; and an upper layer disposed on the glass core and having redistribution lines therein.

A unit refers to a portion in which semiconductor elements are disposed within a die layout and which is to be separated into individual packaging substrates, and the panel comprises a plurality of the units.

A reinforcement structure is disposed on the upper layer and is configured to surround at least a portion of the die layout.

A first unit includes a first die layout and a first reinforcement structure disposed on the first die layout, and a second unit includes a second die layout and a second reinforcement structure disposed on the second die layout.

The second unit may be disposed adjacent to one side of the first unit.

The first reinforcement structure and the second reinforcement structure may be disposed separately from each other.

The panel may further include a third unit.

The third unit may be disposed adjacent to another side of the second unit.

The third unit includes a third die layout and a third reinforcement structure disposed on the third die layout.

The second reinforcement structure and the third reinforcement structure may be disposed separately from each other.

An adhesive layer may be disposed between a lower surface of the reinforcement structure and an upper surface of the panel.

The adhesive layer may be a thermally conductive adhesive layer.

The reinforcement structure includes a frame and an opening.

The frame is a structure configured to surround the die layout.

The opening is connected to an upper surface of the frame and may expose the die layout.

The first unit includes a first die placement region in which semiconductor elements are disposed.

The first reinforcement structure includes a first frame and a first opening.

The first opening may include a region over the first die placement region.

The second unit includes a second die placement region in which semiconductor elements are disposed.

The second reinforcement structure includes a second frame and a second opening.

The second opening includes a region over the second die placement region.

The first opening and the second opening may be distinguished from each other in terms of area or shape.

The reinforcement structure may be formed of a metal (such as aluminum, copper, or stainless steel), ceramic, thermosetting resin, or a composite material.

The panel may include N units.

Each of the N units may include one or more reinforcement structures.

The reinforcement structure included in any one unit may not be physically connected directly to the reinforcement structure included in another unit.

The reinforcement structure may have an opening configured to allow access of the semiconductor element when the semiconductor element is placed in the die layout.

### BRIEF DESCRIPTION OF THE DRAWINGS

FIG. 1 is a conceptual view illustrating a panel according to an embodiment.

FIG. 2 is a conceptual cross-sectional view taken along line A-A′ of FIG. 1.

FIG. 3 is a conceptual cross-sectional view illustrating another example of the panel.

### DESCRIPTION OF THE EMBODIMENTS

Hereinafter, embodiments of the present invention will be described in detail with reference to the accompanying drawings so that those skilled in the art may readily carry out the invention. However, the present invention may be implemented in various different forms and is not limited to the embodiments described herein. Throughout the specification, like reference numerals are used to designate like elements.

In this specification, when an element is referred to as “comprising” or “having” another element, it is intended to indicate the presence or possible addition of one or more other elements, and unless otherwise specifically stated, it does not exclude the presence or addition of other components.

In this specification, when an element is said to be “connected to” another element, it should be understood that it may be directly connected or connected via another intermediate element.

When “B” is referred to as being “on” “A”, it should be understood that “B” may be directly on “A”, or there may be one or more intervening layers between “A” and “B”. That is, the position of “B” should not be interpreted as being limited to direct contact with the surface of “A”.

In this specification, the expression “a combination of ˜” included in Markush-type language refers to a mixture or combination of one or more elements expressed in the Markush group, and accordingly, the disclosure is intended to include one or more elements selected from the Markush group.

The phrase “A and/or B” as used herein means “A or B, or A and B”.

The terms “first” and “second”, or “A” and “B”, as used herein are intended to distinguish between different elements unless otherwise specified.

Singular expressions in this specification may include plural expressions unless the context clearly indicates otherwise.

It should be noted that the drawings included in the present specification are not necessarily drawn to scale, and may be exaggerated for clarity. The elements shown in the drawings should not be interpreted as being limited to specific sizes or proportions.

The glass core has various advantages when applied as a support for a packaging substrate. Specifically, the glass core may be manufactured in a large area, and formation of large-area cavities is relatively easy using methods such as etching. In addition, even when high-frequency elements are mounted, there is little possibility of generating parasitic elements.

However, the glass core also has disadvantages when applied as a support for a packaging substrate. Glass has a brittle nature.

The glass core is relatively vulnerable to impact and may be easily broken. Additionally, it may exhibit warpage to a degree that requires control.

The inventors propose that individual reinforcement structures be pre-disposed on the panel substrate so as to surround the die layout, in particular, to suppress damage to portions intended for singulation into individual packaging substrates, and to help suppress warpage of the substrate.

The embodiment is distinguished from the approach of disposing a single large-area structure to suppress warpage of the panel substrate. Further, the embodiment enables the mounting of semiconductor elements through openings that may be disposed at different sizes and positions. In addition, the die layouts are individually separated, facilitating subsequent singulation.

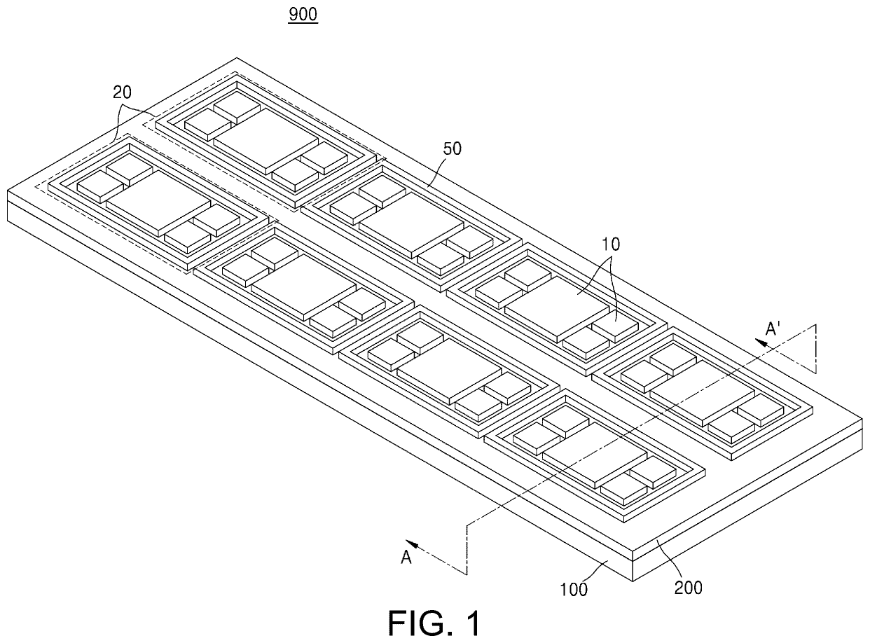

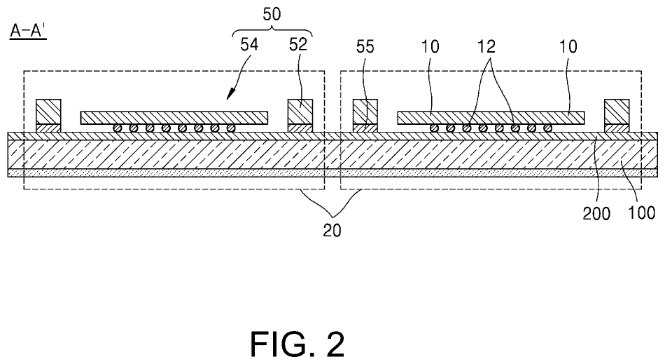

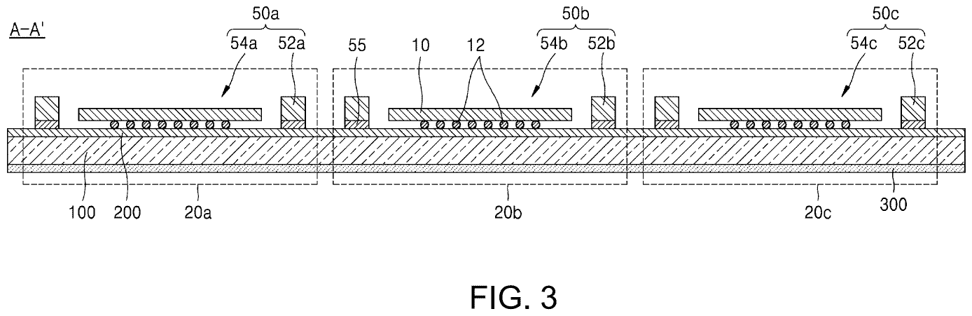

FIG. 1 is a conceptual view illustrating a panel according to an embodiment, FIG. 2 is a conceptual cross-sectional view taken along line A-A′ of FIG. 1, and FIG. 3 is a conceptual cross-sectional view illustrating another example of the panel. Hereinafter, the embodiment will be described in further detail.

In order to achieve the above object, a panel 900 according to one embodiment of the present embodiment comprises: a glass core 100 having a width or length of 10 cm or more; and an upper layer 200 disposed on the glass core 100 and having redistribution lines therein.

It is preferable that the glass core 100 applies a glass plate used for semiconductors. For example, borosilicate glass plates, alkali-free glass plates, or the like may be used, but the application is not limited thereto.

The glass core 100 may comprise through-vias penetrating the glass plate in a thickness direction and/or cavities penetrating the glass plate in the thickness direction or forming a recessed surface. Through-electrodes may be formed in the through-vias to enable electrical signal transmission in the vertical direction of the glass core, and cavity elements may be disposed in the cavities.

The glass core 100 may be applied in the form of a large-area panel. For example, the glass core 100, which is the panel, may have an overall rectangular shape with a width and/or length of 10 cm or more. The glass core 100 may have a width and/or length of 10 cm or more, 15 cm or more, 20 cm or more, 25 cm or more, 30 cm or more, 35 cm or more, 40 cm or more, or 45 cm or more. The glass core 100 may have a width and/or length of 150 cm or less, 130 cm or less, 110 cm or less, 90 cm or less, 70 cm or less, or 60 cm or less.

An upper layer 200 may be disposed on the glass core 100. Additionally, a lower layer 300 may optionally be disposed beneath the glass core 100. The upper layer 200 and the lower layer 300 may each comprise redistribution lines applicable to the field of packaging substrates.

The glass core 100 is processed in the form of a panel and may be singulated into one or more pieces to form individual packaging substrates.

A unit 20 refers to a portion in which a semiconductor element 2 is disposed within a die layout and which is to be separated into an individual packaging substrate.

A plurality of the units 20 may be disposed on the panel 900.

A reinforcement structure 50 is a structure configured to surround at least a portion of the die layout. The reinforcement structure 50 is disposed on the upper layer 200 when the semiconductor element is mounted on the upper layer 200. If the semiconductor element is disposed on the upper side of the upper layer 200 and under the lower layer 300, the reinforcement structure 50 may be disposed on both the upper side of the upper layer 200 and the lower side of the lower layer 300.

The reinforcement structures 50 are individually disposed for each unit 20.

A first unit 20a comprises a first die layout and a first reinforcement structure 50a disposed on the first die layout.

A second unit 20b comprises a second die layout and a second reinforcement structure 50b disposed on the second die layout.

When the second unit 20b is disposed adjacent to one side of the first unit 20a, the first reinforcement structure 50a and the second reinforcement structure 50b are separated from each other.

The panel 900 may further comprise a third unit 20c.

The third unit 20c may be disposed adjacent to the other side of the second unit 20b.

The third unit 20c comprises a third die layout and a third reinforcement structure 50c disposed on the third die layout.

The second reinforcement structure 50b and the third reinforcement structure 50c may be disposed separately from each other.

The panel 900 may comprise N units 20. In this case, each of the N units 20 may comprise one or more reinforcement structures 50.

The reinforcement structure 50 included in any one unit 20 may not be physically connected directly to the reinforcement structure 50 included in another unit 20.

The reinforcement structure 50 comprises a frame 52 and an opening 54.

The frame 52 is a structure configured to surround the die layout.

The opening 54 is connected to an upper surface of the frame 52 and opens the die layout.

The first unit 20a comprises a first die placement region in which a semiconductor element 10 is disposed.

The first reinforcement structure 50a comprises a first frame 52a and a first opening 54a.

The first opening 54a may comprise a region over the first die placement region.

The second unit 20b may comprise a second die placement region in which a semiconductor element 10 is disposed.

The second reinforcement structure 50b comprises a second frame 52b and a second opening 54b.

The second opening 54b may comprise a region over the second die placement region.

The first opening 54a and the second opening 54b may be different in area or shape. In the embodiment, each reinforcement structure has its own opening, and the openings may have different sizes and shapes. This enables individual units with various types of die placement regions to be mounted on a single panel, allowing for efficient processing.

For example, aluminum or an aluminum alloy may be applied to the reinforcement structure 50.

Various materials such as metals (e.g., aluminum, copper, stainless steel), ceramics, thermosetting resins, and composite materials may be applied to the reinforcement structure 50.

The reinforcement structure 50 may have an opening 54 through which the semiconductor element 10 can be inserted or removed when the semiconductor element 10 is placed in the die layout.

The reinforcement structure 50 may have an opening 54 through which an upper surface of the semiconductor element 10 can be exposed when the semiconductor element 10 is placed in the die layout.

An adhesive layer 55 may be disposed between a lower surface of the reinforcement structure 50 and an upper surface of the panel 900.

The adhesive layer 55 may be a thermally conductive adhesive layer.

As an example, the thermally conductive adhesive layer may be applied as a cured adhesive layer formed of a thermally conductive filler-containing silicone resin, urethane resin, acrylate resin, epoxy resin, BMI, or the like, but is not limited thereto.

The embodiment enables easy placement of semiconductor elements through openings that can be disposed in different sizes and positions. In addition, the die layouts are individually separated, thereby facilitating subsequent singulation.

The panel according to the embodiment may provide a panel comprising individual packaging substrates, in which a reinforcement structure advantageous for large-area substrate processing is disposed, thereby improving reliability.

The panel according to the embodiment may provide a panel having a reinforcement structure capable of suppressing glass breakage and reducing warpage during large-area substrate processing.

Although the preferred embodiment of the present invention has been described in detail above, the scope of the present invention is not limited thereto. Various modifications and improvements by those skilled in the art, based on the basic concept defined in the following claims, shall also fall within the scope of the present invention.

What is claimed is:

1. A panel comprising:
a glass core having a width or length of 10 cm or more; and an upper layer disposed on the glass core and having redistribution lines therein,
wherein a unit is a portion in which a semiconductor element is disposed within a die layout and which is to be separated into an individual packaging substrate,
wherein a plurality of the units are disposed on the panel,
a reinforcement structure is disposed on the upper layer and is configured to surround at least a portion of the die layout,
a first unit comprises a first die layout and a first reinforcement structure disposed on the first die layout,
a second unit comprises a second die layout and a second reinforcement structure disposed on the second die layout,
the second unit is disposed adjacent to one side of the first unit, and
the first reinforcement structure and the second reinforcement structure are disposed separately from each other.

2. The panel of claim 1,
wherein the panel further comprises a third unit,
the third unit is disposed adjacent to other side of the second unit,
the third unit comprises a third die layout and a third reinforcement structure disposed on the third die layout, and
the second reinforcement structure and the third reinforcement structure are disposed separately from each other.

3. The panel of claim 1,
wherein an adhesive layer is disposed between a lower surface of the reinforcement structure and an upper surface of the panel,
and the adhesive layer is a thermally conductive adhesive layer.

4. The panel of claim 1,
wherein the reinforcement structure comprises a frame and an opening,
the frame is a structure configured to surround the die layout,
and the opening is connected to an upper surface of the frame and opens the die layout.

5. The panel of claim 1,
wherein the first unit comprises a first die placement region in which a semiconductor element is disposed,
the first reinforcement structure comprises a first frame and a first opening,
and the first opening comprises a region over the first die placement region.

6. The panel of claim 5,
wherein the second unit comprises a second die placement region in which a semiconductor element is disposed,
the second reinforcement structure comprises a second frame and a second opening,
the second opening comprises a region over the second die placement region,
and the first opening and the second opening are different in area or shape.

7. The panel of claim 1,
wherein the reinforcement structure is of a metal (such as aluminum, copper, or stainless steel), a ceramic, a thermosetting resin, or a composite material.

8. The panel of claim 1,
wherein the panel comprises N units,
and each of the N units comprises one or more reinforcement structures.

9. The panel of claim 8,
wherein the reinforcement structure included in any one unit is not physically connected directly to the reinforcement structure included in another unit.

10. The panel of claim 1,
wherein the reinforcement structure has an opening configured to allow access of a semiconductor element when the semiconductor element is placed in the die layout.
